(19) United States
(12) Patent Application Publication
(10) Pub. No.: US 2015/0318456 A1
(43) Pub. Date: Nov. 5, 2015

(54) OPTICAL LENS DEVICE

(71) Applicant: Jo-Han HSU, Taoyuan City (TW)

(72) Inventor: Jo-Han HSU, Taoyuan City (TW)

(21) Appl. No.: 14/700,149

(22) Filed: Apr. 30, 2015

(30) Foreign Application Priority Data
Apr. 30, 2014 (TW) 103115455

(51) Int. Cl. H01L 33/58

(52) U.S. Cl. CPC H01L 33/58

(57) ABSTRACT

The present invention provides an optical lens device, comprising a LED module and an optical lens. The structure of the optical lens is symmetrically formed with respect to a central axis, the structure comprising a funnel-like upper face, a base face and a lateral face. At the center of base face, there is projectingly provided with a light-guiding structure. Rays emitted from the LED module are allowed to enter into the optical lens through the light-guiding structure, and a part of wide-angle rays are totally reflected by a lateral side of the light-guiding structure to be directed toward the upper face, and then emitted through the lateral face after totally reflected by the upper face. Accordingly, the side illuminating rays may be increased by directing the part of wide-angle rays to be emitted through the lateral face, and thus the luminous efficacy of side illumination is enhanced.

### CROSS-REFERENCE TO RELATED APPLICATIONS

This non-provisional application claims priority claim under 35 U.S.C. §119(a) on Taiwan Patent Application No. 103115455 filed Apr. 30, 2014, the entire contents of which are incorporated herein by reference.

### FIELD OF THE INVENTION

The present invention is related to an optical lens device, particularly to an optical lens device capable of side illumination.

### BACKGROUND

Light-emitting diodes (LEDs) are readily to be combined with various types of products around us due to features including small volume, long service life, low driving voltage, rapid response, and so on, and thus used for the purpose of illumination or display. The LEDs are applied in unidirectional lights including flashlights, searchlights, desk lamps, and so on with nice effect owing to unidirectional emission of light. However, there are still many technical problems to be overcome if the LEDs are designed for the application in lamps or displays which are capable of side illumination.

Referring to FIG. 1, there is shown a structural diagram of a conventional side illuminating optical lens device. As illustrated in the figure, the optical lens device 100 comprises an optical lens 11, an LED module 13 and a base plate 15.

The optical lens 11 is provided with a central axis 101, and the structure of the optical lens 11 is symmetrically formed with respect to the central axis 101. The optical lens 11 comprises a funnel-like upper face 111, a lateral face 113 and a base face 115. The LED module 13 is located on the extension of the central axis 101, and provided on the base plate 15. Several rays, such as rays L1, L2, for example, at various angles may be emitted when light is emitted from the LED module 13. The small-angle ray L1 at a smaller angle with respect to the central axis 101 may be totally reflected by the upper face 111 and then emitted through the lateral face 113, in such a way that the ray L1 is emitted in an approximately horizontal direction, achieving the effect of side illumination or wide-angle illumination. Additionally, the wide-angle ray L2 having a wider angle with respect to the central axis 101 is totally reflected by the lateral face 113 firstly, and then emitted through the upper face 111. The light-emitting angle of the ray L2 with respect to the central axis 101 is smaller, such that the effect of side illumination could not be achieved.

Accordingly, the present invention will propose a novel optical lens device in which all wide-angle or small-angle rays generated by an LED module may be totally reflected within the optical lens after they are allowed to enter into the optical lens, and then emitted through a lateral face of the optical lens, whereby the rays for side illumination are increased. Thus, the object of enhancing the luminous efficacy of side illumination may be achieved.

### SUMMARY

It is one object of the present invention to provide an optical lens device, in which an optical lens comprises an upper face, a base face and a lateral face. At the center of the base face, there is projectingly provided with a light-guiding structure, through which rays emitted from an LED module are allowed to enter into the optical lens. A part of wide-angle rays are totally reflected by a lateral side of the light-guiding structure so as to be directed toward the upper face, and then emitted through the lateral face after totally reflected by the upper face. In this way, the side illuminating rays will be increased when the wide-angle rays are directed to be emitted through the lateral face. Thus, the luminous efficacy of side illumination is enhanced.

It is one object of the present invention to provide an optical lens device, in which a part of the upper face in an area near the central axis of an optical lens is provided as a refracting surface. Then, when small-angle rays close to the central axis are emitted from the LED module, the small-angle rays will be refracted or reflected by the refracting surface, so as to achieve the object of wide light-emitting angle.

It is one object of the present invention to provide an optical lens device, in which a part of the upper face in an area near the central axis of an optical lens is provided as a saw-toothed or rough refracting surface. Small-angle rays emitted from the LED module will be refracted by the saw-toothed or rough refracting surface to be emitted scatteringly, resulting in the scattering effect.

It is one object of the present invention to provide an optical lens device, in which an optical lens is provided on a lateral face thereof with a saw-toothed or rough refracting surface, in such a way that the scattering effect may be also achieved for side illumination.

For achieving above objects, the present invention provides an optical lens device, comprising an LED module, and an optical lens having a central axis, a symmetric structure being formed with respect to the central axis, and the LED module being provided on the extension of the central axis, the optical lens comprising: an upper face forming a funnel-like surface along the central axis; a base face projectingly provided at the center thereof with a light-guiding structure; and a lateral face connecting the base face with the upper face; in which rays emitted from the LED module are allowed to enter into the optical lens through the light-guiding structure, and a part of the rays are totally reflected by a lateral side of the light-guiding structure to be directed toward the upper face and then emitted through the lateral face after totally reflected by the upper face.

In one embodiment of the present invention, the upper face is a totally reflecting curved surface or inclined surface.

In one embodiment of the present invention, the upper face is surroundingly provided with a reflecting surface and a refracting surface along the central axis, in which the reflecting surface and the refracting surface are curved surfaces or inclined surfaces. The reflecting surface is provided between the lateral face and the refracting surface, while the refracting surface is provided between the reflecting surface and the central axis of the optical lens. An angle between the refracting surface and the central axis is wider than that between the reflecting surface and the central axis.

In one embodiment of the present invention, the width of a light-emitting surface of the LED module is W and the radius of the refracting surface is P, in which 0≦P≦W is set.

In one embodiment of the present invention, the width of a light-emitting surface of the LED module is W and the width of the light-guiding structure is R, in which W≦R is set.

In one embodiment of the present invention, the upper face is surroundingly provided with a reflecting surface and a refracting surface along the central axis, in which the reflecting surface is a curved surface or inclined surface, while the refracting surface is a saw-toothed surface or rough surface. The reflecting surface is provided between the lateral face and the refracting surface, while the refracting surface is provided between the reflecting surface and the central axis of the optical lens.

In one embodiment of the present invention, the optical lens device further comprises a base plate. The LED module is provided on the base plate, while the base face of the optical lens is provided over the base plate by means of a plurality of props.

In one embodiment of the present invention, the LED module is provided under the light-guiding structure, with a medium having a refractive index lower than that of material of the optical lens being presented between the LED module and the light-guiding structure.

In one embodiment of the present invention, the lateral side of the light-guiding structure is presented as a vertical surface, inclined surface or curved surface.

In one embodiment of the present invention, the lateral face of the optical lens is a vertical surface, inclined surface, curved surface or combining surface consisting of the vertical surface, inclined surface and curved surface.

In one embodiment of the present invention, the lateral face of the optical lens is provided with a refracting surface in a saw-toothed mode or rough mode.

In one embodiment of the present invention, a light incident surface of the light-guiding structure is a plane surface, concave surface, convex surface or rough surface.

### BRIEF DESCRIPTION OF THE DRAWINGS

The structure as well as preferred modes of use, further objects, and advantages of this invention will be best understood by referring to the following detailed description of some illustrative embodiments in conjunction with the accompanying drawings, in which:

FIG. 1 is a structural diagram of a conventional side illuminating optical lens device.

FIG. 2A is a perspective diagram of an optical lens according to one embodiment of the present invention.

FIG. 2B is a perspective cross-sectional view of an optical lens according to one embodiment of the present invention.

FIG. 3 is a structural diagram of an optical lens device according to one embodiment of the present invention.

FIG. 4A is a structural top view of an optical lens device according to one embodiment of the present invention.

FIG. 4B is a structural top view of an optical lens device according to a further embodiment of the present invention.

FIG. 5 is a structural diagram of an optical lens device according to a further embodiment of the present invention.

FIG. 6 is a structural diagram of an optical lens device according to a further embodiment of the present invention.

FIG. 7 is a diagram with labeled dimensions for the light-emitting surface, refracting surface and light-guiding structure of the optical lens device of the present invention.

FIG. 8 is a structural diagram of an optical lens device according to a further embodiment of the present invention.

FIG. 9 is a structural diagram of an optical lens device according to a further embodiment of the present invention.

FIG. 10 is a structural diagram of an optical lens device according to a further embodiment of the present invention.

FIG. 11 is a structural diagram of an optical lens device according to a further embodiment of the present invention.

FIG. 12 is a structural diagram of an optical lens device according to a further embodiment of the present invention.

FIG. 13 is a structural diagram of an optical lens device according to a further embodiment of the present invention.

FIG. 14 is a structural diagram of an optical lens device according to a further embodiment of the present invention.

FIG. 15 is a structural diagram of an optical lens device according to a further embodiment of the present invention.

FIG. 16 is a structural diagram of an optical lens device according to a further embodiment of the present invention.

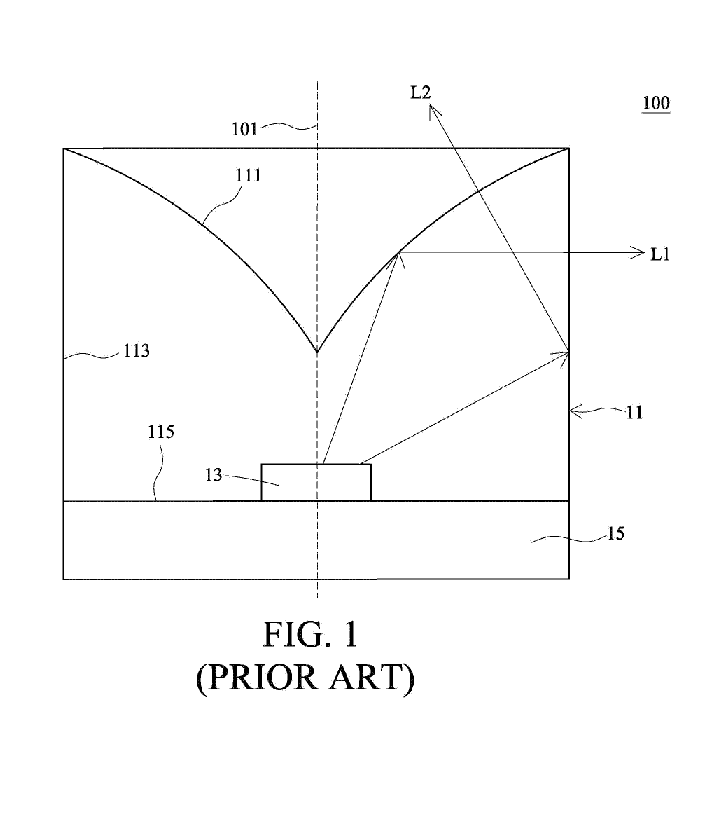

### DETAILED DESCRIPTION OF THE PREFERRED EMBODIMENTS

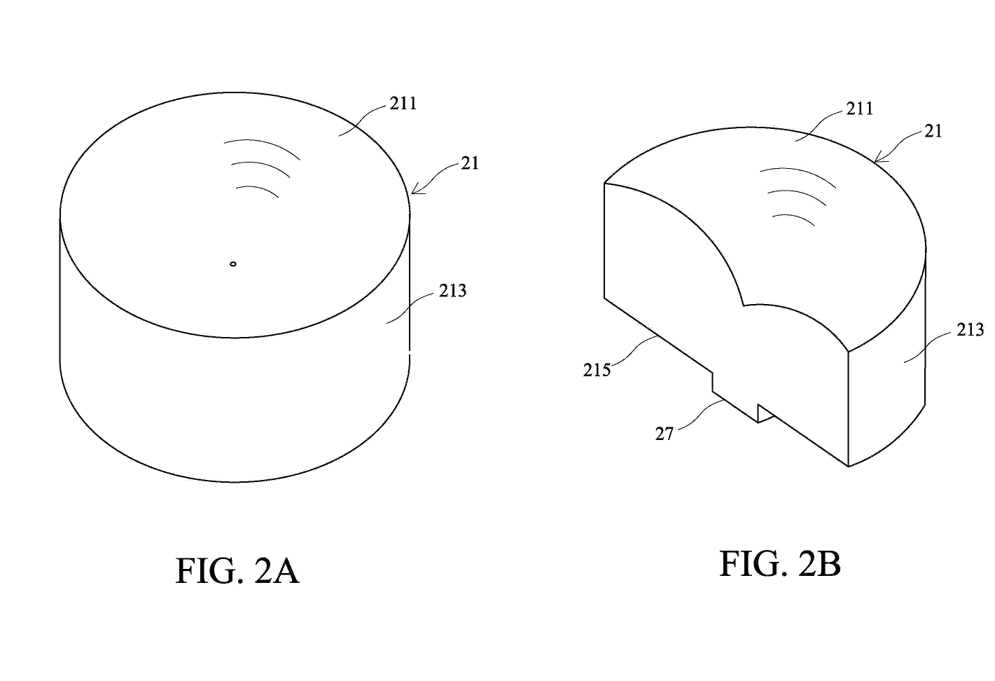

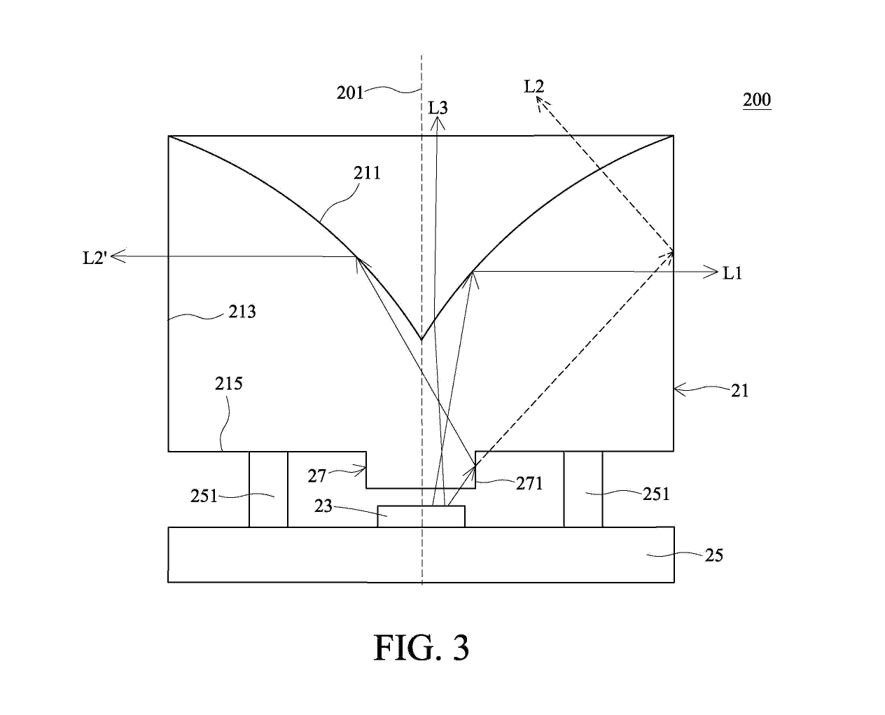

Referring to FIGS. 2A and 2B, there are shown a perspective diagram and a cross-sectional diagram, respectively, of an optical lens according to one embodiment of the present invention. Moreover, referring to FIG. 3 cooperatively, there is shown a structural diagram of an optical lens device according to one embodiment of the present invention. As illustrated in the figures, the optical lens device 200 comprises an optical lens 21 and a light-emitting diode (LED) module 23.

The optical lens 21 is made of Acrylic, PMMA, glass or other visible light-permeable materials. The optical lens 21 is provided with a central axis 201, and the structure of the optical lens 21 is symmetrically formed with respect to the central axis 201. The optical lens 21 comprises an upper face 211, a lateral face 213 and a base face 215. The upper face 211 is recessed along the central axis 201 to form a funnel-like surface. This upper face 211 may be also a totally reflecting curved surface or inclined surface. On the underside of the base face 215, there is projectingly provided at the center with a light-guiding structure 27. A lateral face 213 is used to connect the upper face 211 with the base face 215.

The LED module 23 is provided on the extension of the central axis 201, and located under the light-guiding structure 27. The LED module 23 is composed of a plurality of LEDs, so as to emit several rays at various angles. In the present invention, the rays emitted from the LED module 23 may be allowed to enter into the optical lens 21 through the light-guiding structure 27.

When a small-angle ray L1 at a smaller angle with respect to the central axis 201 is emitted from the LED module 23, the ray L1 is totally reflected by the base face 211 and then emitted through the lateral face 213, in such a way that the ray L1 is emitted in an approximately horizontal direction, achieving the effect of side illumination.

Additionally, when a wide-angle ray L2 at a wider angle with respect to the central axis 201 is emitted from the LED module 23, the ray L2 will be emitted toward the lateral face 213 to be totally reflected and then emitted through the upper face 211 if the light-guiding structure 27 isn't provided with the optical lens 21. Only upward illumination is possible for this ray L2 having a smaller light-emitting angle with respect to the central axis 201.

Then, after the light-guiding structure 27 is provided for the optical lens 21 of the present invention, a wide-angle ray L2′ may be emitted toward a lateral side 271 of the light-guiding structure 27 firstly to be totally reflected, and subsequently directed toward the upper face 211, so as to be totally reflected at the upper face 211 and then emitted through the lateral face 213. Thus, the ray L2′ is emitted in an approximately horizontal direction, achieving the effect of side illumination.

With the addition of light-guiding structure 27, herein, a part of wide-angle rays L2′ emitted from the LED module 23 may be adjusted as being emitted at the lateral face 213 instead of being emitted at the upper face 211 originally. In this case, the rays for side illumination or emitted at wide angle may be increased, so as to enhance the luminous efficacy of side illumination.

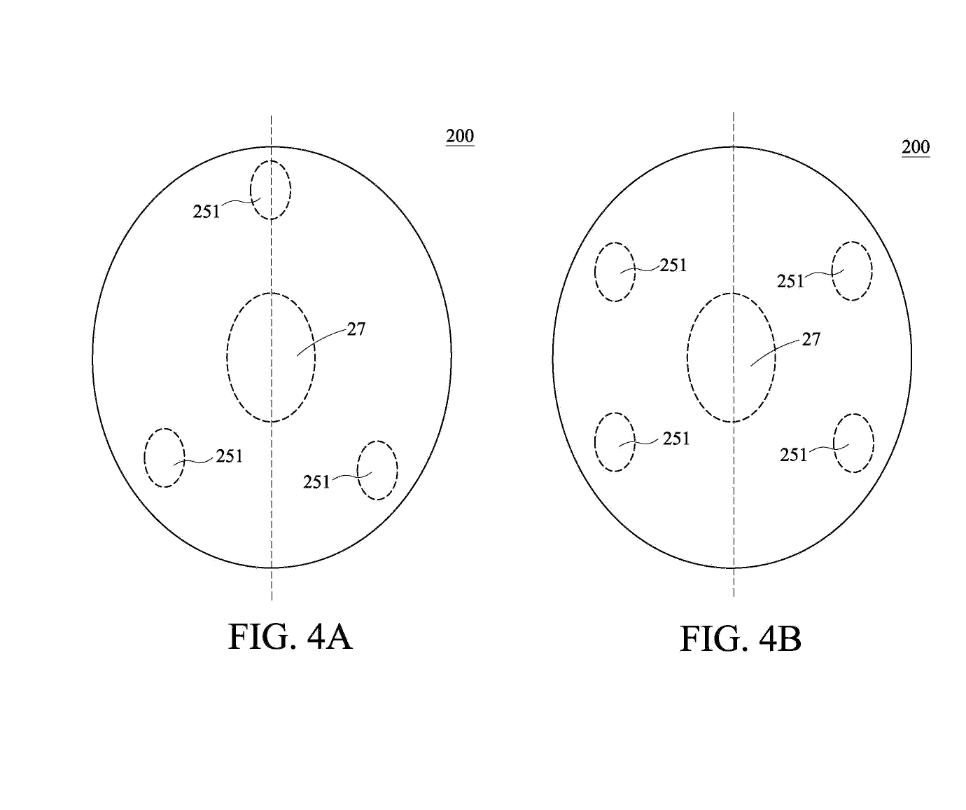

Further, the LED module 23 of the present invention may be provided on a base plate 25, while the base face 215 of the optical lens 21 is fixedly provided over the base plate 25 by means of a plurality of props 251 (such as three props in FIG. 4A, four props in Fig, 4B, or more than four props). The props 251 may be provided on two sides of the central axis 201 symmetrically. Moreover, a medium, having a refractive index lower than that of material of the optical lens 21, such as air, is presented between the LED module 23 and the light-guiding structure 27.

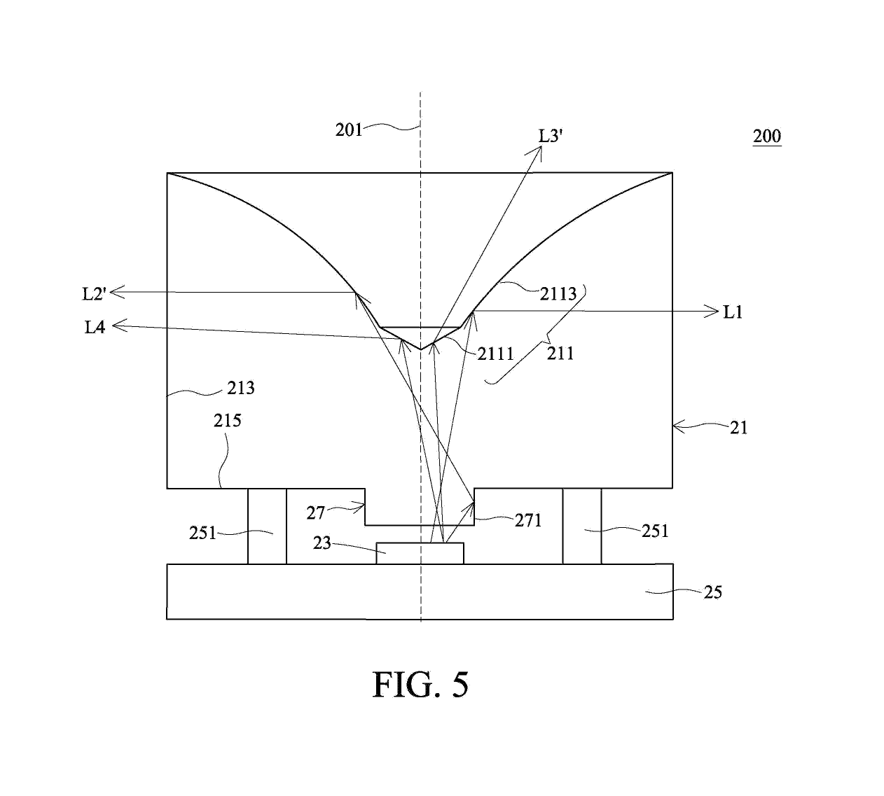

Referring to FIG. 5, there is shown a structural diagram of an optical lens device according to a further embodiment of the present invention. As illustrated in the figure, the upper face 211 of the optical lens 21 of the present invention is surroundingly provided with a refracting surface 2111 and a reflecting surface 2113 along the central axis 201.

The refracting surface 2111 and the reflecting surface 2113 are curved surfaces or inclined surfaces at various angles. The reflecting surface 2113 is provided between the lateral face 213 and the refracting surface 2111, while the refracting surface 2111 is provided between the reflecting surface 2113 and the central axis 201. In one embodiment of the present invention, the angle between the refracting surface 2111 and the central axis 201 is wider than that between the reflecting surface 2113 and the central axis 201.

Referring to FIG. 3, again, when a small-angle ray L3, close to the central axis 201 and having a positive angle with respect to the central axis 201, is emitted from the LED module 23, the ray L3 will be refracted by the totally reflecting upper face 211 to be emitted through the upper face 211 in an approximately vertical direction.

In FIG. 5, in comparison with FIG. 3, a part of the upper face 211, in the area near the central axis 201, of the optical lens 21, is provided as the refracting surface 2111. When a small-angle ray L3′, close to the central axis 201 and having a positive angle with respect to the central axis 201, is emitted from the LED module 23, the ray L3′ will be emitted toward the refracting surface 2111, and refracted by the refracting surface 2111 so as to be emitted through the upper face 211 at a wider light-emitting angle. Then, the ray L3′ is adjusted as being emitted at a wide angle instead of being emitted at the original small angle in the vertical direction, due to refraction by means of the refracting surface 211. Thus, the object of wide light-emitting angle is achieved.

Moreover, a small-angle ray L4, close to the central axis 201 and having a negative angle with respect to the central axis 201, is further emitted from the LED module 23. This ray L4 will be emitted toward the refracting surface 2111 on the opposite side with respect to the central axis 201, and reflected by the refracting surface 2111 so as to be emitted through the lateral face 213 at a wider light-emitting angle.

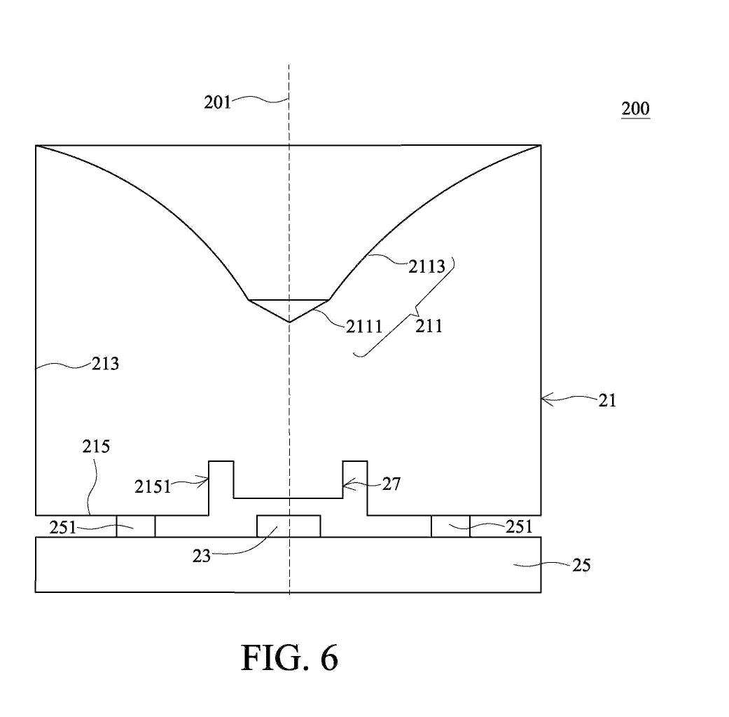

Referring to FIG. 6, there is shown a structural diagram of an optical lens device according to a further embodiment of the present invention. In the optical lens 21 of this embodiment, the base face 215 is further provided with a recessed region 2151 inside which the light-guiding structure 27 may be selectively provided projectingly. The light-guiding structure 27, herein, either projectingly provided on the underside of the base face 215 directly or projectingly provided inside the recessed region 2151 of the base face 215, may be within the scope of claims intended to be claimed by each embodiment of the present invention.

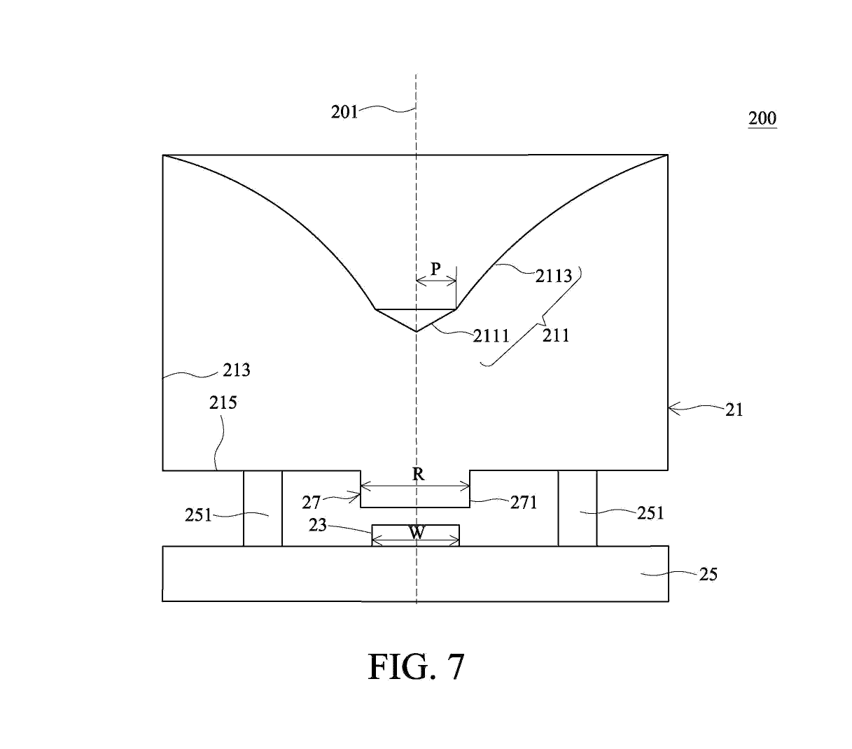

Referring to FIG. 7, there is shown a diagram with labelled dimensions for the light-emitting surface, refracting surface and light-guiding structure of the optical lens device of the present invention. In the LED module 23 of the present invention, as illustrated in the figure, the width of the light-emitting surface is W, the radius of the refracting surface 2111 is P, and the width of the light-guiding structure 27 is R.

In one embodiment of the present invention, 0≦P≦W is set, such that all the small-angle rays may be emitted at wide angles due to refraction or reflection by means of the refracting surface 2111. W≦R is set, such that all the rays emitted from the light-emitting surface of the LED module 23 may be allowed to enter into the optical lens 21 through the light-guiding structure 27. Furthermore, the above specification for dimensional setting among the width (W) of P, the radius (P) of refracting surface 2111 and the width (R) of light-guiding structure 27 is only one preferred embodiment of the present invention, and not limited thereto in the practical design.

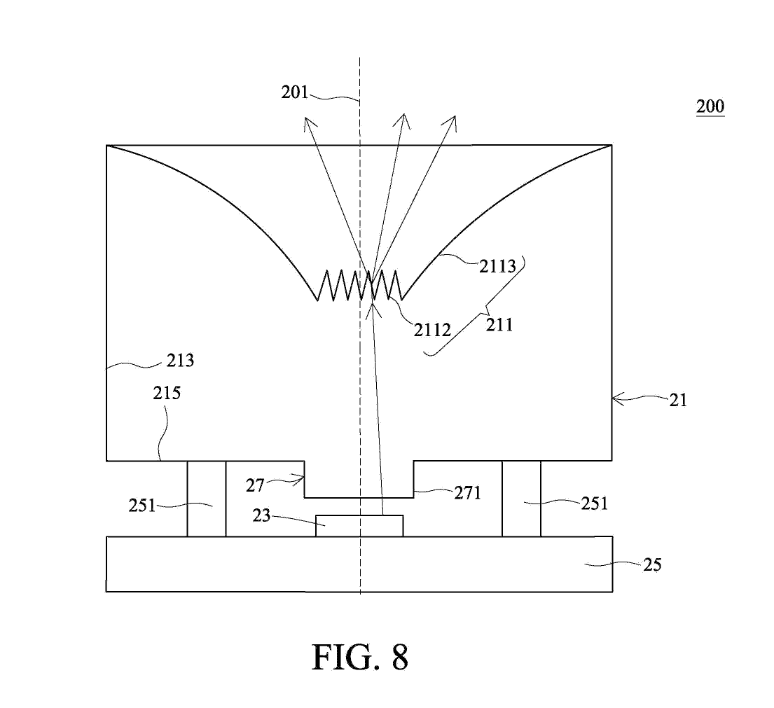

Referring to FIG. 8, there is shown a structural diagram of an optical lens device according to a further embodiment of the present invention. As illustrated in the figure, the upper face 211 of the optical lens 21 of the present invention is surroundingly provided with a refracting surface 2112 and a reflecting surface 2113 along the central axis 201.

The refracting surface 2112 is a saw-toothed surface or rough surface, while the reflecting surface 2113 is a curved surface or inclined surface. The reflecting surface 2113 is provided between the lateral face 213 and the refracting surface 2112, while the refracting surface 2112 is provided between the reflecting surface 2113 and the central axis 201. When a small-angle ray, close to the central axis 201, is emitted from the LED module 23, the ray will be emitted toward the refracting surface 2112, and refracted by the refracting surface 2112 to be emitted scatteringly. Thus, the scattering effect is achieved.

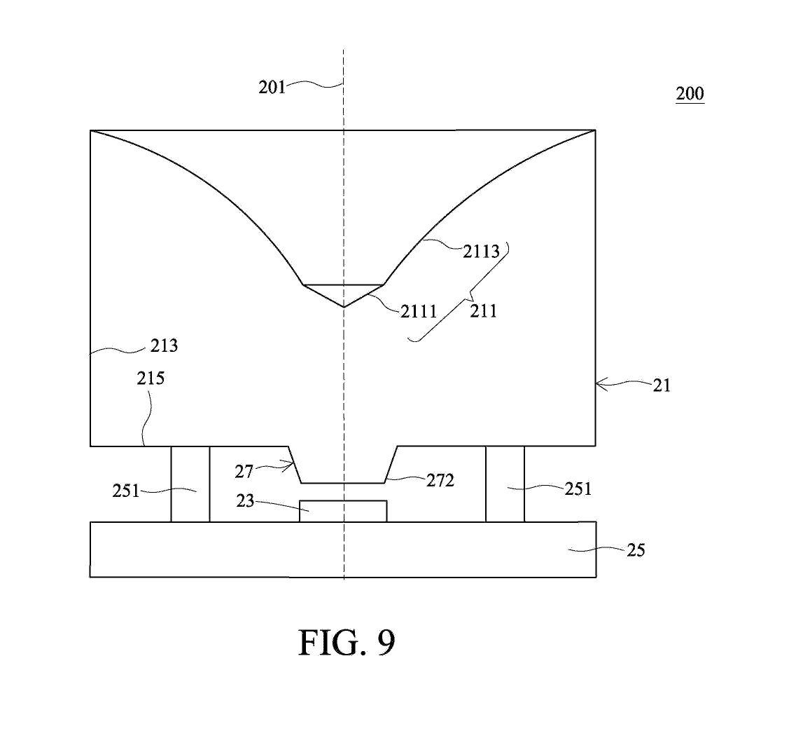

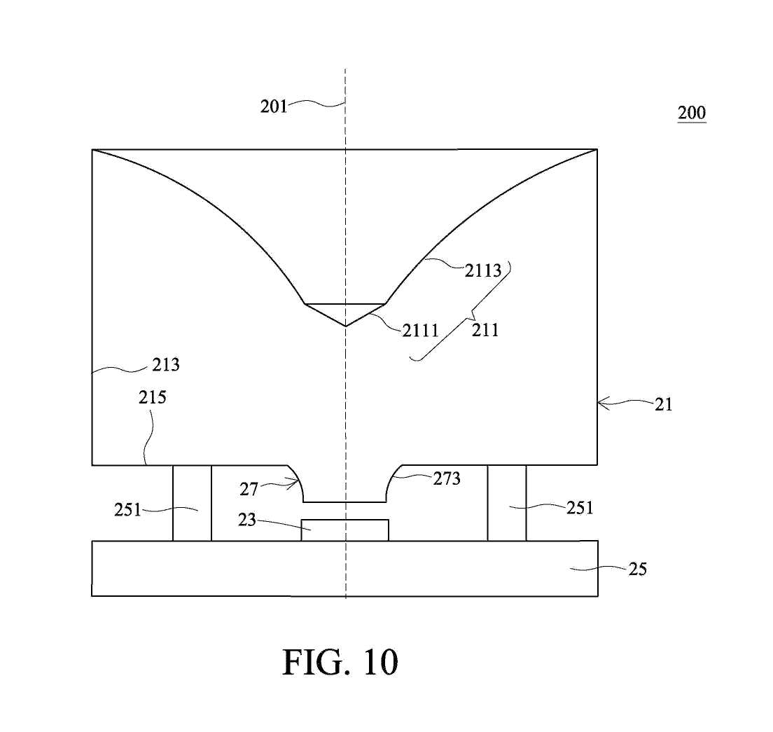

Moreover, referring to FIGS. 3, 5 to 8, a vertical lateral side 271 is designed for the light-guiding structure 27 of the present invention. Otherwise, referring to FIG. 9, an inclined lateral side 272 is designed for the light-guiding structure 27 of the present invention. Otherwise, referring to FIG. 10, a curved lateral side 273 is designed for the light-guiding structure 27 of the present invention.

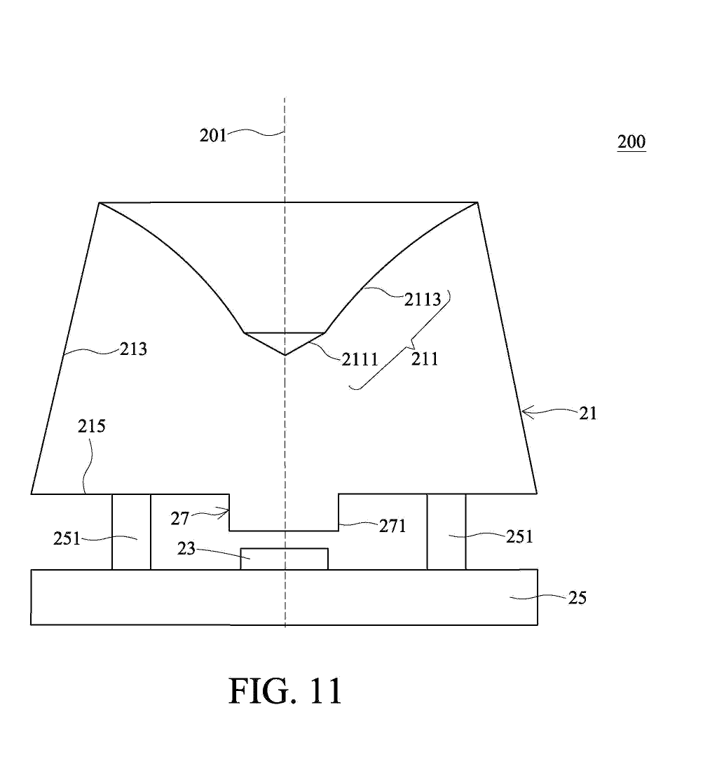

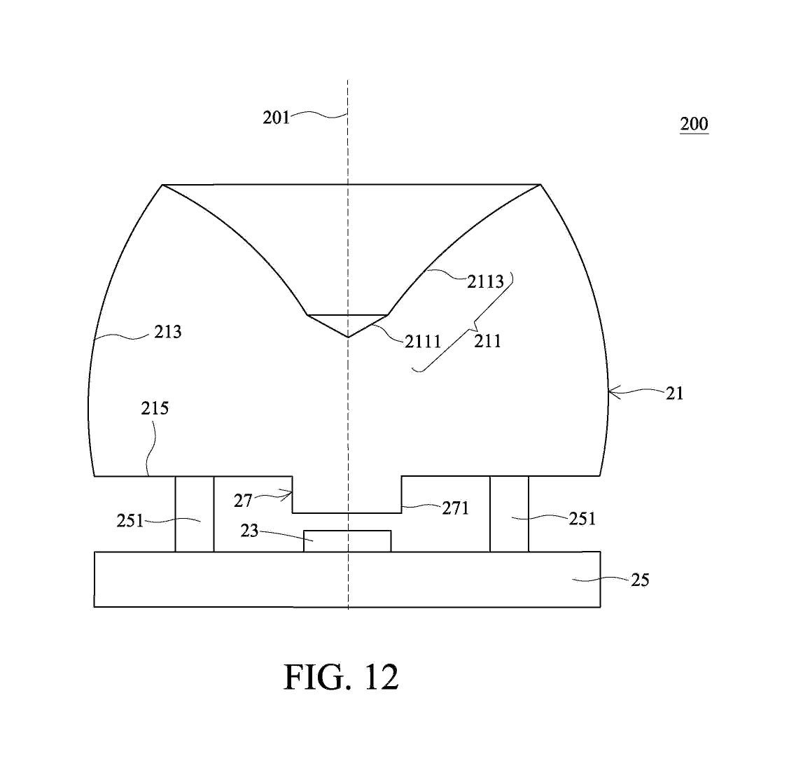

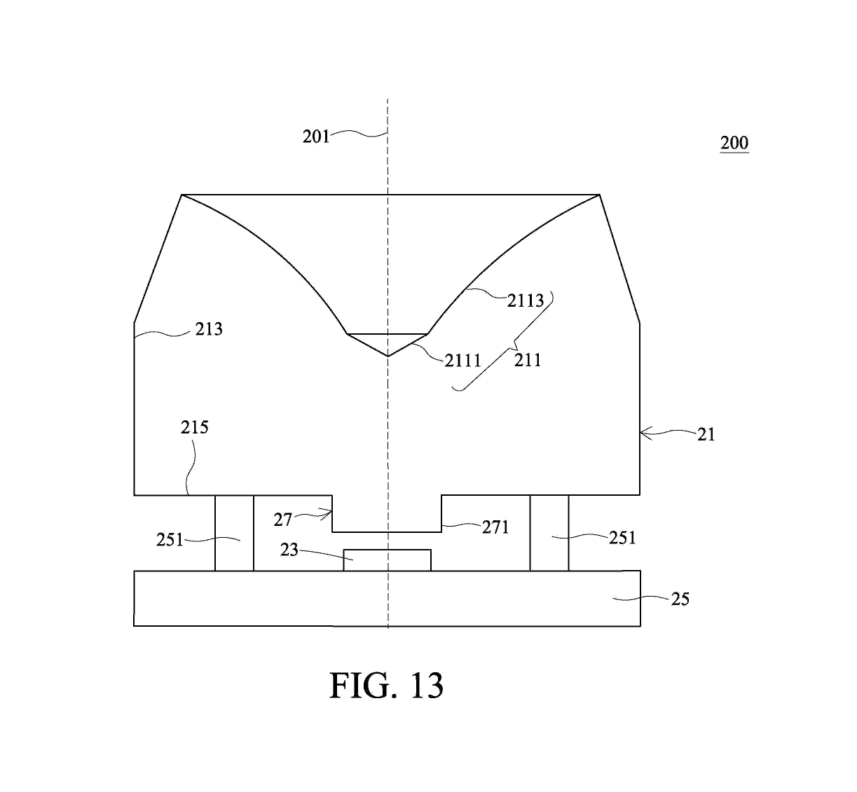

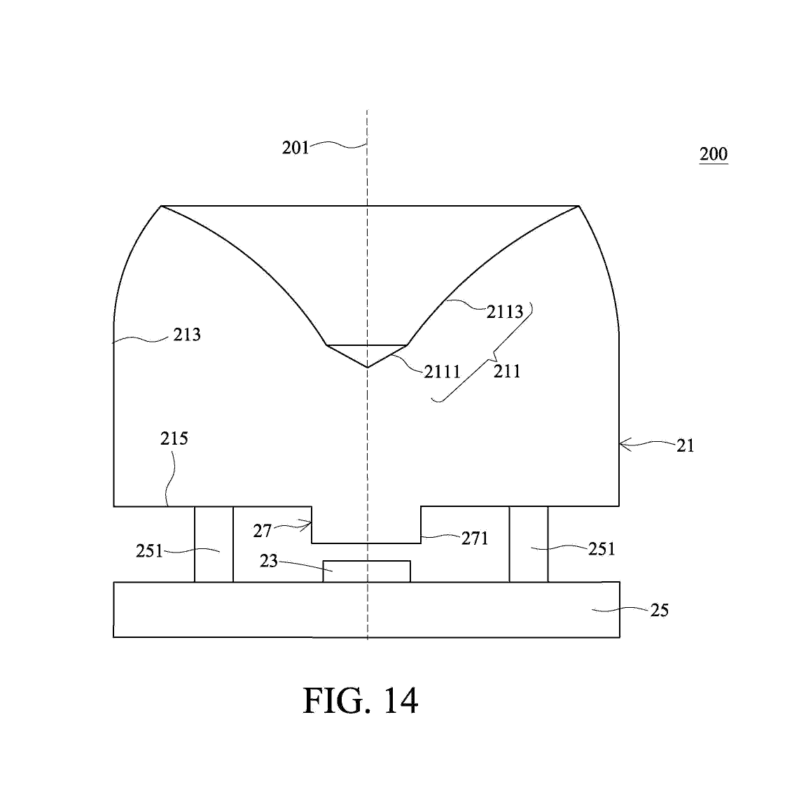

Further, referring to FIGS. 3, 5 to 10, the lateral face 213 of the optical lens 21 of the present invention may be designed as a vertical surface. Otherwise, referring to FIG. 11, the lateral face 213 of the optical lens 21 of the present invention may be designed as an inclined surface. Otherwise, referring to FIG. 12, the lateral face 213 of the optical lens 21 of the present invention may be designed as a curved surface. Otherwise, referring to FIGS. 13 and 14, the lateral face 213 of the optical lens 21 of the present invention may be designed as a combining surface consisting of the vertical surface, inclined surface and curved surface.

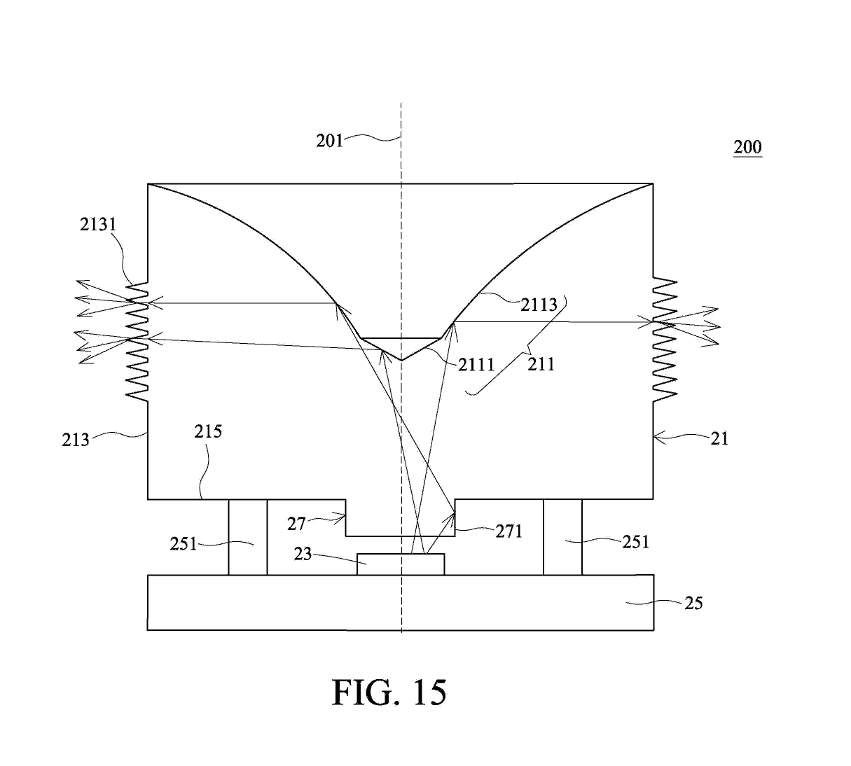

Referring to FIG. 15, otherwise, the lateral face 213 of the optical lens 21 is further provided with a refracting surface 2131 in a saw-toothed mode or rough mode. With the refracting surface 2131 of the lateral face 213, the ray totally reflected by the upper face 211 may be refracted to be emitted scatteringly. Thus, the scattering effect is also achieved for side illumination.

Furthermore, the above variations in shapes of upper face 211, lateral face 213 or light-guiding structure 27 may be cooperated with one another to compose various embodiments, which should not be described repeatedly herein.

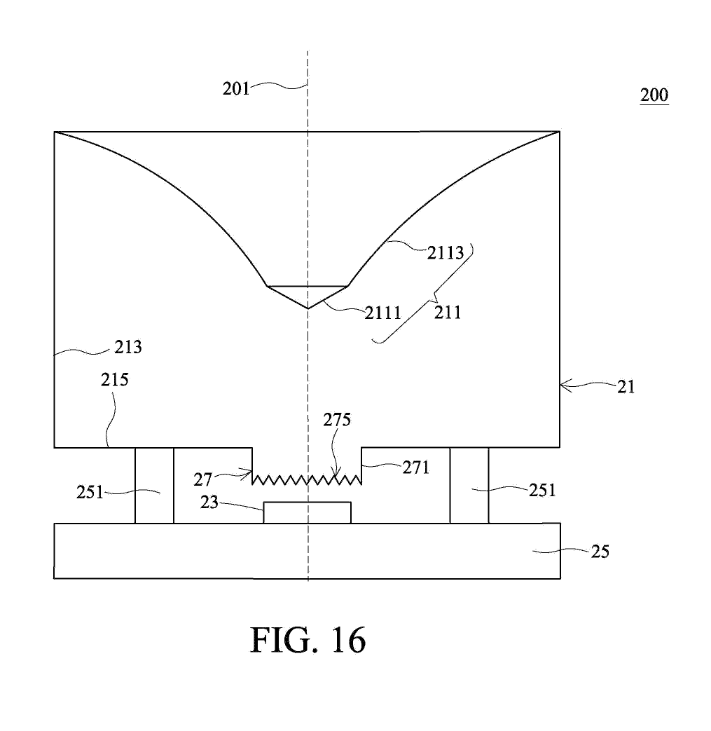

Referring to FIG. 16, there is shown a structural diagram of an optical lens device according to a further embodiment of the present invention. In each of above embodiments, the light incident surface of the light-guiding structure 27 is designed as a horizontal surface. In the present invention, otherwise, a light incident surface 275 of the light-guiding structure 27 is designed as a concave surface, convex surface or rough surface.

When the rays generated by the LED module 23 are emitted toward the light incident surface 275 in the saw-toothed or rough mode, the rays will be refracted by the light incident surface 275 to be emitted. The scattered incident rays will be allowed to enter into the optical lens 21 through the light-guiding structure 27, so as to generate more refracted rays at the upper face 211. Thus, better scattering effect may be achieved for the optical lens 21.

The above disclosure is only the preferred embodiment of the present invention, and not used for limiting the scope of the present invention. All equivalent variations and modifications on the basis of shapes, structures, features and spirits described in claims of the present invention should be included in the claims of the present invention.

1. An optical lens device, comprising:
a light-emitting diode (LED) module; and
an optical lens having a central axis, a symmetric structure being formed with respect to said central axis, and said LED module being provided on the extension of said central axis, said optical lens comprising:
an upper face forming a funnel-like surface along said central axis;
a base face projectingly provided at the center thereof with a light-guiding structure; and
a lateral face connecting said base face with said upper face;
wherein rays emitted from said LED module are allowed to enter into said optical lens through said light-guiding structure, and a part of said rays are totally reflected by a lateral side of said light-guiding structure to be directed toward said upper face and then emitted through said lateral face after totally reflected by said upper face.

2. The optical lens device according to claim 1, wherein said upper face is a totally reflecting curved surface or inclined surface.

3. The optical lens device according to claim 1, wherein said upper face is surroundingly provided with a reflecting surface and a refracting surface along said central axis, said reflecting surface and said refracting surface being curved surfaces or inclined surfaces, said reflecting surface being provided between said lateral face and said refracting surface, while said refracting surface being provided between said reflecting surface and said central axis of said optical lens, an angle between said refracting surface and said central axis being wider than that between said reflecting surface and said central axis.

4. The optical lens device according to claim 3, wherein the width of a light-emitting surface of said LED module is W and the radius of said refracting surface is P, in which 0≦P≦W is set.

5. The optical lens device according to claim 1, wherein the width of a light-emitting surface of said LED module is W and the width of said light-guiding structure is R, in which W≦R is set.

6. The optical lens device according to claim 1, wherein said upper face is surroundingly provided with a reflecting surface and a refracting surface along said central axis, said reflecting surface being a curved surface or inclined surface, while said refracting surface being a saw-toothed surface or rough surface, said reflecting surface being provided between said lateral face and said refracting surface, while said refracting surface being provided between said reflecting surface and said central axis of said optical lens.

7. The optical lens device according to claim 1, further comprising a base plate, said LED module being provided on said base plate, while said base face of said optical lens being provided over said base plate by means of a plurality of props.

8. The optical lens device according to claim 7, wherein said LED module is provided under said light-guiding structure, with a medium having a refractive index lower than that of material of said optical lens being presented between said LED module and said light-guiding structure.

9. The optical lens device according to claim 1, wherein said lateral side of said light-guiding structure is presented as a vertical surface, inclined surface or curved surface.

10. The optical lens device according to claim 1, wherein said lateral face of said optical lens is a vertical surface, inclined surface, curved surface or combining surface consisting of the vertical surface, inclined surface and curved surface.

11. The optical lens device according to claim 1, wherein said lateral face of said optical lens is provided with a refracting surface in a saw-toothed mode or rough mode.

12. The optical lens device according to claim 1, wherein a light incident surface of said light-guiding structure is a plane surface, concave surface, convex surface or rough surface.
